(19) United States
(12) Patent Application Publication
(10) Pub. No.: US 2021/0090907 A1
(43) Pub. Date: Mar. 25, 2021

(54) Encapsulation Method for Flip Chip

(71) Applicants: Quan KE, Guangdong (CN); Bing ZHAO, Shanghai (CN)

(72) Inventors: Quan Ke, Guangdong (CN); Futing Yi, Beijing (CN); Ming Pan, Jiangsu (CN); Bing Zhao, Shanghai (CN)

(21) Appl. No.: 17/095,727

(22) Filed: Nov. 11, 2020

Related U.S. Application Data
(63) Continuation-in-part of application No. 15/757,902, filed on Mar. 6, 2018.

(30) Foreign Application Priority Data
Sep. 11, 2015 (CN) 201510579955.1

(51) Int. Cl. H01L 21/56; H01L 23/31; H01L 23/29

(52) U.S. Cl. CPC H01L 21/563; H01L 23/293; H01L 23/3121; H01L 23/3114

(57) ABSTRACT

A method for bonding electrodes of a flip-chip die to corresponding electrical contacts of an encapsulation substrate and a flip chip. The method comprises steps of: S11: applying a first metal layer on the electrode surface of the flip-chip die and the structured surface of the encapsulation substrate as a base layer; S12: transferring, by means of photolithography, a structural pattern of a mask onto the base layer; S13: electroforming metal, according to the transferred structural pattern, to form electrical connections between electrodes of the flip-chip die and the corresponding electrical contacts of an encapsulation substrate; and S14: cutting off undesired electrical connections between different electrodes and between different electrical contacts by removing unnecessary metal areas.

### BACKGROUND OF THE INVENTION

### 1. Field of the Invention

The present invention relates to a bonding method for semiconductor encapsulation, and more particularly, to a method for bonding electrodes of a flip-chip die to corresponding electrical contacts of an encapsulation substrate and a flip chip manufactured by such a bonding method.

### 2. Description of the Related Art

With the development of flip chip technology, especially the widespread use of semiconductor LEDs (light emitting diodes), flip-chip encapsulation for semiconductor LED chips has become a hot topic. There are three bonding methods conventionally used for flip-chip encapsulation, i.e. eutectic, solder paste and elargol for die bonding. No matter which bonding method is used, high precision of die bonding is a must, as the distance between positive and negative electrodes of a flip chip should be small enough due to compact size of the chip, and accurate alignment between the electrodes of the chip and corresponding electrical contacts on the encapsulation substrate is usually needed before bonding; flip chip eutectic technology requires expensive production equipment and materials, which makes it not cost effective; encapsulation methods using solder paste and elargol, because of relatively low reliability and poor thermal conductivity, can't be used for encapsulation of high-power flip chips; and flip-LED technology has been developed for a long time, but is not mature enough to be widely used, since there are still quite some technical bottlenecks.

In addition to the three conventional bonding methods mentioned above, there is also a newly emerging electromagnetic pulse-weld bonding method as described in the Chinese patent application “Encapsulation Method for a Flip Chip” (Publication No. CN103094135A). An advantage of this bonding method is that a chip electrode and a substrate contact are atomically connected, which is very conducive for heat dissipation of high-power flip chips. However, it is found that, when using the electromagnetic pulse-weld method for bonding, accuracy of alignment between the chip electrode and the substrate electrode becomes a key factor that affects encapsulation efficiency and finished product. Another encapsulation method, as suggested in the Chinese patent application “Encapsulation Method and Device for a Flip Chip” (Publication No. CN104658929A), is that, after bonding of the chip die to a metal substrate, the metal substrate is cut along an insulating region between electrodes on the chip by means of laser cutting or the like to cut off electrical connections between electrodes of the chip die and thus cut off electrical connections between electrodes of the corresponding chip, but a potential risk of this method is that, such a cutting process will lead to great stress on the chip, although it only cuts the metal, it might pass through two electrodes that have been fixed, and thus adversely affect the chip. It is desirable to have a method to improve the accuracy of electrical bonding of the flip-chip die to the encapsulation substrate with simplified processes, which can form subtle electrical connections between the chip electrodes and the electrical contacts on the substrate to meet the rigorous manufacturing requirements of high-power, compact-sized semiconductor chips.

### BRIEF SUMMARY OF THE INVENTION

The technical problem to be solved in the present invention is to provide an encapsulation method for manufacturing flip chips to overcome the defects of conventional encapsulation bonding methods in semiconductor industry.

The present invention solves the above-mentioned technical problem through the following technical solutions:

The present invention provides a method for bonding electrodes of a flip-chip die to corresponding electrical contacts of an encapsulation substrate,

wherein the flip-chip die has an electrode surface with at least two electrodes and a base surface opposite the electrode surface, and the encapsulation substrate comprises a substrate body having a structured surface with at least two electrical contacts and a back surface opposite the structured surface, and

wherein the base surface of the flip-chip die is placed in the substrate body or on the structured surface of the substrate body, so that the electrode surface of the flip-chip die and the structured surface of the substrate body face the same direction.

This method comprises steps of:

S11: applying a first metal layer on the electrode surface of the flip-chip die and the structured surface of the encapsulation substrate as a base layer;

S12: transferring, by means of photolithography, a structural pattern of a mask onto the base layer;

S13: electroforming metal, according to the transferred structural pattern, to form electrical connections between electrodes of the flip-chip die and the corresponding electrical contacts of an encapsulation substrate; and

S14: cutting off undesired electrical connections between different electrodes and between different electrical contacts by removing unnecessary metal areas.

Preferably, step S12 comprises steps of:

S121: applying a layer of a first photoresist on the first metal layer; and

S122: structuring the layer of the first photoresist by means of photolithography according to the structural pattern of the mask, so that in the areas on top of the electrodes of the flip-chip die and on top of the electrical contacts of the encapsulation substrate, as well as in the areas that are desired to form electrical connections between the electrodes and the corresponding electrical contacts, the first photoresist is removed to expose the underlying first metal layer, while in other areas the first photoresist is remained.

By applying said layer of the first photoresist, the binding force between different components of the flip chip can be enhanced, and the electrode surface of the flip-chip dies and the structural surface of the encapsulation substrate can be protected.

Preferably, step S13 comprises steps of:

S131: electroforming metal on the exposed portions of the first metal layer to fill the gaps between the remained first photoresist; and

S132: removing the remaining first photoresist to expose the underlying first metal layer.

Preferably, step S13 comprises a step of removing the still exposed portions of the first metal layer.

Preferably, step S11 comprises steps of:

S111: applying a layer of a second photoresist on the electrode surface of the flip-chip die and the structured surface of the encapsulation substrate;

S112. structuring the layer of the second photoresist by means of photolithography, so that in the areas on top of the electrodes of the flip-chip die and on top of the electrical contacts of encapsulation substrate the second photoresist is removed, while in other areas the second photoresist are remained; and

S113: coating metal on the structured layer of the second photoresist, as well as on top of the exposed areas of the electrodes of the flip-chip die and the electrical contacts of encapsulation substrate, such as to form said first metal layer.

Preferably, step S113 comprises: first coating a chromium layer and then coating a gold layer on top of the chromium layer. With this arrangement, the binding strength, stability and electrical conductivity can be significantly improved.

Optionally, the flip-chip die is placed in a recess or a hollow structure of the substrate body of the encapsulation substrate.

Optionally, the electrode surface of the flip-chip die and the structured surface of the substrate body are substantially on a common plane. According to the present invention, here the word “substantially” means a tolerance within tens of micrometers. With such an arrangement, the thickness of the flip chip after bonding and encapsulation can be significantly reduced.

In an optional embodiment, the flip-chip die is placed in a hollow structure of the substrate body of the encapsulation substrate, and said method further comprises a step S10 before step S11, i.e. placing the back surface of the substrate body of the encapsulation substrate on a transparent and adhesive underlayer, and after S14, removing said transparent and adhesive underlayer. When using hollow structures (through-holes) on the substrate body to accommodate the flip-chip dies, the transparent and adhesive underlayer provided in this embodiment can allow light transmittance from the encapsulation substrate on one hand, and ensure stable mounting of the flip-chip dies in the hollow structure of the substrate body on the other hand.

Preferably, a plurality of flip-chip dies are bonded to the same encapsulation substrate according to above steps S11-S14 and then cut into a plurality of chips. This will achieve high productivity in mass production.

Preferably, the flip-chip die is for an LED chip.

Preferably, the substrate body is made of silicon, resin, glass or ceramic.

The present invention further provides a flip chip, which comprises a flip-chip die and an encapsulation substrate, wherein the flip-chip die has an electrode surface with at least two electrodes and a base surface opposite the electrode surface, and the encapsulation substrate comprises a substrate body having a structured surface with at least two first electrical contacts and a back surface opposite the structured surface, and wherein the base surface of the flip-chip die is placed in the substrate body or on the structured surface of the substrate body, with the electrode surface of the flip-chip die and the structured surface of the substrate body facing the same direction.

Said flip chip further comprises a structured metal layer formed by metal-electroforming on top of the electrodes of the flip-chip die and on top of the electrical contacts of the encapsulation substrate, as well as in gaps between the electrodes of the flip-chip die and the corresponding electrical contacts of the encapsulation substrate, such as to form electrical bonding between the electrodes of the flip-chip die and corresponding electrical contacts of the encapsulation substrate, while there is no metal electroformed in isolation areas between different electrodes of the flip-chip die and in isolation areas between different electrical contacts of the encapsulation substrate.

Preferably, the encapsulation substrate further comprises a control circuit provided on the structured surface to control the functionality of the flip chip, wherein the control circuit is electrically connected to corresponding electrical contacts of the encapsulation substrate.

Preferably, the encapsulation substrate further comprises an interface circuit on the structured surface for electrically connecting the flip chip to an external device, wherein the interface circuit is electrically connected to the control circuit.

Preferably, said flip chip is an LED chip.

Preferably, the substrate body of the encapsulation substrate is made of silicon, resin, glass or ceramic.

Preferably, the flip-chip die is placed in a recess or hollow structure of the substrate body of the encapsulation substrate.

Optionally, the electrode surface of the flip-chip die and the structured surface of the substrate body are substantially on a common plane. The tolerance here can be within tens of micrometers.

With the solution proposed by the present invention, electroforming and photoetching technologies are utilized for bonding the flip-chip die and the encapsulation substrate, so as to ensure positional accuracy of the electrodes of the flip-chip die and the corresponding electrical contacts of the encapsulation substrate, which can meet the need of a small spacing between electrodes of the flip chip. Meanwhile, thick photoresist process is used to realize fine metal connections between the chip electrodes and the electrical contacts on the substrate, and heat dissipation of high-power flip chips is significantly improved by effectively reducing thermal resistance. What's more, the entire encapsulation process is simplified, and higher productivity can be achieved.

Moreover, according to the present invention, electrical bonding can be done without using extra soldering material, and no additional pressure or temperature conditions are needed during manufacturing. This inventive method is cost effective and further promotes heat dissipation of the flip-chip.

### BRIEF DESCRIPTION OF THE SEVERAL VIEWS OF THE DRAWINGS

For better understanding of the invention, the following detailed description of the preferred embodiments is illustrated in conjunction with the following drawings, in which:

FIG. 1 is a flowchart of an encapsulation method for the flip chip of Embodiment 1 of the present invention.

FIG. 2 is a schematic structural diagram of an intermediate product obtained after performing the step 101 in the encapsulation method for the flip chip of the Embodiment 1 of the present invention.

FIG. 3 is a schematic structural diagram of an intermediate product obtained after performing the step 102 in the encapsulation method for the flip chip of Embodiment 1 of the present invention.

FIG. 4 is a schematic structural diagram of an intermediate product obtained after performing the step 103 in the encapsulation method according to Embodiment 1 of the present invention.

FIG. 5 is a schematic structural diagram of an intermediate product obtained after performing the step 104 in the encapsulation method according to Embodiment 1 of the present invention.

FIG. 6 is a schematic structural diagram of an intermediate product obtained after performing the step 105 in the encapsulation method f according to Embodiment 1 of the present invention.

FIG. 7 is a schematic structural diagram of an intermediate product obtained after performing the step 106 in the encapsulation method according to Embodiment 1 of the present invention.

FIG. 8 is a schematic structural diagram of an intermediate product obtained after performing the step 107 in the encapsulation method according to Embodiment 1 of the present invention.

FIG. 9 is a schematic structural diagram of an intermediate product obtained after performing the step 108 in the encapsulation method according to Embodiment 1 of the present invention.

FIG. 10 is a schematic structural diagram of an intermediate product obtained after performing the step 109 in the encapsulation method according to Embodiment 1 of the present invention.

FIG. 11 is a schematic structural diagram of a product obtained after performing the step 110 in the encapsulation method according to Embodiment 1 of the present invention.

FIG. 12 is a flowchart of an encapsulation method according to Embodiment 2 of the present invention.

FIG. 13 is a top view of an intermediate product obtained after performing the step 201 in the encapsulation method according to Embodiment 2 of the present invention.

FIG. 14 is a side view of an intermediate product obtained after performing the step 201 in the encapsulation method according to Embodiment 2 of the present invention.

FIG. 15 is a schematic structural diagram of an intermediate product obtained after performing the step 202 in the encapsulation method according to Embodiment 2 of the present invention.

FIG. 16 is a schematic structural diagram of an intermediate product obtained after performing the step 203 in the encapsulation method according to Embodiment 2 of the present invention.

FIG. 17 is a schematic structural diagram of an intermediate product obtained after performing the step 205 in the encapsulation method according to Embodiment 2 of the present invention.

FIG. 18 is a schematic structural diagram of an intermediate product obtained after performing the step 206 in the encapsulation method according to Embodiment 2 of the present invention.

FIG. 19 is a top view of an intermediate product obtained after performing the step 208 in the encapsulation method according to Embodiment 2 of the present invention.

FIG. 20 is a side view of an intermediate product obtained after performing the step 208 in the encapsulation method according to Embodiment 2 of the present invention.

FIG. 21 is a schematic structural diagram of an intermediate product obtained after performing the step 209 in the encapsulation method according to Embodiment 2 of the present invention.

FIG. 22 is a schematic structural diagram of an intermediate product obtained after performing the step 210 in the encapsulation method according to Embodiment 2 of the present invention.

FIG. 23 is a schematic structural diagram of a product obtained after performing the step 211 in the encapsulation method according to Embodiment 2 of the present invention.

FIG. 24 is a top diagram of the encapsulation substrate.

FIG. 25 is a flowchart of the bonding method for the flip-chip die and encapsulation substrate according to Embodiment 3 of the present invention.

FIG. 26 is a schematic structural diagram of an intermediate product obtained after performing the step 302 in Embodiment 3 of the present invention.

FIG. 27 is a schematic structural diagram of an intermediate product obtained in performing the step 303 in Embodiment 3 of the present invention.

FIG. 28 is a schematic structural diagram of the process of exposure in performing the step 303 in Embodiment 3 of the present invention.

FIG. 29 is a top view of the exposed areas in performing the step 303 in Embodiment 3 of the present invention.

FIG. 30 is a schematic structural diagram of an intermediate product obtained after performing the step 303 in Embodiment 3 of the present invention.

FIG. 31 is a top view of an intermediate product obtained after performing the step 303 in Embodiment 3 of the present invention.

FIG. 32 is a schematic structural diagram of an intermediate product obtained after performing the step 304 in Embodiment 3 of the present invention.

FIG. 33 is a schematic structural diagram of an intermediate product obtained in performing the step 305 in Embodiment 3 of the present invention.

FIG. 34 is a schematic structural diagram of the process of exposure in performing the step 305 in Embodiment 3 of the present invention.

FIG. 35 is a top view of the exposed areas in performing the step 305 in Embodiment 3 of the present invention.

FIG. 36 is a schematic structural diagram of an intermediate product obtained after performing the step 305 in Embodiment 3 of the present invention.

FIG. 37 is a top view of an intermediate product obtained after performing the step 305 in Embodiment 3 of the present invention.

FIG. 38 is a schematic structural diagram of an intermediate product obtained in performing the step 306 in Embodiment 3 of the present invention.

FIG. 39 is a schematic structural diagram of an intermediate product obtained in performing the step 307 in Embodiment 3 of the present invention.

FIG. 40 is a schematic structural diagram of an intermediate product obtained in performing the step 308 in Embodiment 3 of the present invention.

FIG. 41 is a schematic structural diagram of a finished product obtained in the Embodiment 3 of the present invention.

FIG. 42 is a flowchart of the bonding method for the flip-chip die and encapsulation substrate according to Embodiment 4 of the present invention.

FIG. 43 is a schematic structural diagram of an intermediate product obtained after performing the step 401 in Embodiment 4 of the present invention.

FIG. 44 is a top view of an intermediate product obtained after performing the step 402 in Embodiment 4 of the present invention.

FIG. 45 is a schematic structural diagram of an intermediate product obtained after performing the step 402 in Embodiment 4 of the present invention.

FIG. 46 is a schematic structural diagram of an intermediate product obtained in performing the step 403 in Embodiment 4 of the present invention

FIG. 47 is a schematic structural diagram of the process of exposure in performing the step 403 in Embodiment 4 of the present invention.

FIG. 48 is a top view of the exposed areas in performing the step 403 in Embodiment 4 of the present invention.

FIG. 49 is a schematic structural diagram of an intermediate product obtained after performing the step 403 in Embodiment 4 of the present invention.

FIG. 50 is a top view of an intermediate product obtained after performing the step 403 in Embodiment 4 of the present invention.

FIG. 51 is a schematic structural diagram of an intermediate product obtained after performing the step 404 in Embodiment 4 of the present invention.

FIG. 52 is a schematic structural diagram of an intermediate product obtained in performing the step 405 in Embodiment 4 of the present invention.

FIG. 53 is a schematic structural diagram of the process of exposure in performing the step 405 in Embodiment 4 of the present invention.

FIG. 54 is a schematic structural diagram of the exposed areas in performing the step 405 in Embodiment 4 of the present invention.

FIG. 55 is a schematic structural diagram of an intermediate product obtained after performing the step 405 in Embodiment 4 of the present invention.

FIG. 56 is a top view of an intermediate product obtained after performing the step 405 in Embodiment 4 of the present invention.

FIG. 57 is a schematic structural diagram of an intermediate product obtained in performing the step 406 in Embodiment 4 of the present invention.

FIG. 58 is a schematic structural diagram of an intermediate product obtained in performing the step 407 in Embodiment 4 of the present invention.

FIG. 59 is a schematic structural diagram of an intermediate product obtained in performing the step 408 in Embodiment 4 of the present invention.

FIG. 60 is a schematic structural diagram of a finished product obtained in the Embodiment 4 of the present invention.

### DETAILED DESCRIPTION OF THE INVENTION

### Embodiment 1

As shown in FIG. 1, the encapsulation method for the flip chip in the embodiment comprises the following steps:

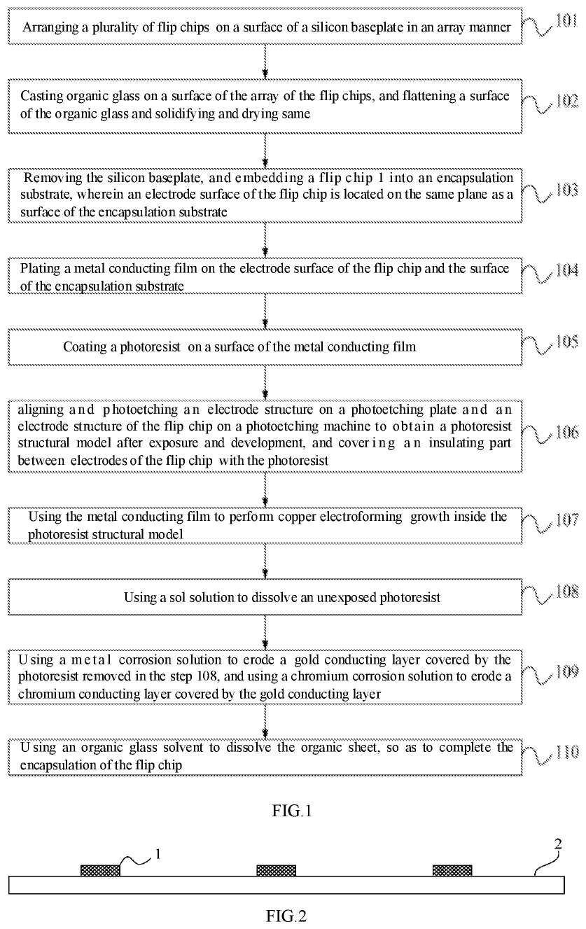

Step 101, arranging a plurality of flip chips 1 on a surface of a silicon baseplate 2 in an array manner, and contacting the electrode surface of the flip chip 1 with a surface of the silicon baseplate 2, wherein, preferably, the distance between two adjacent flip chips 1 is 6 mm, and a schematic structural diagram of an intermediate product obtained after performing the step 101 is as shown in FIG. 2.

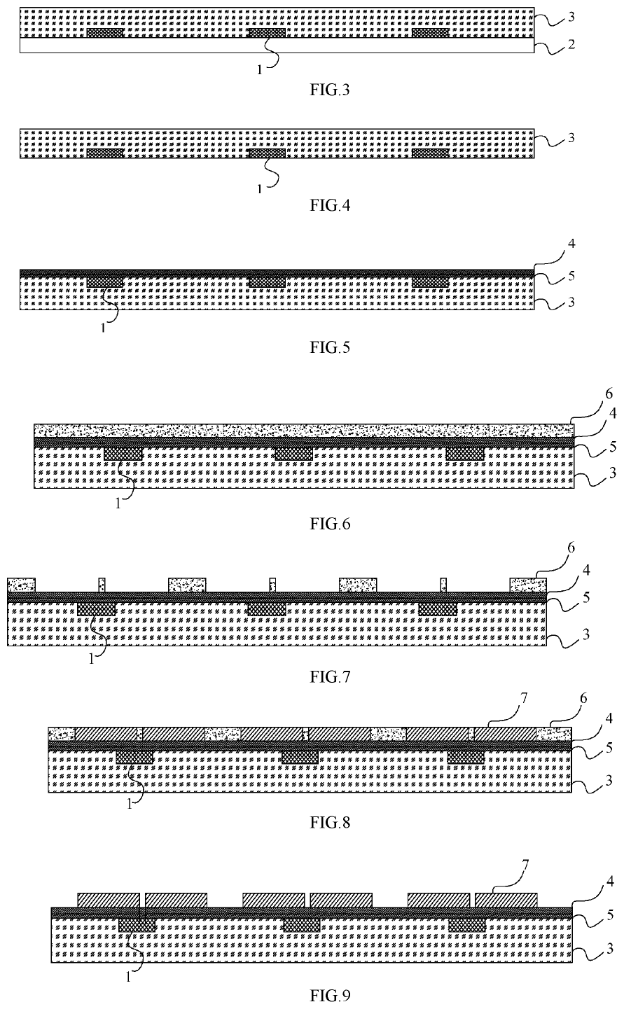

Step 102, casting organic glass 3 on a surface of the array of the flip chips 1, and flattening a surface of the organic glass 3 and solidifying and drying the organic glass 3 to form an organic sheet having a thickness of 2 mm, and the organic sheet is used as an encapsulation substrate, and a schematic structural diagram of an intermediate product obtained after performing the step 102 is as shown in FIG. 3.

Step 103, removing the silicon baseplate 2, specifically, the silicon baseplate can be removed by grinding or chemical method, so that the flip chip 1 is embedded in the encapsulation substrate and the electrode surface of the flip chip is located on the same plane as the surface of the encapsulation substrate, thus the encapsulation substrate with the flip chip 1 embedded in an array manner is obtained, and so that the electrode surface of the flip chip 1 and the surface of the encapsulation substrate are well coincide, and a schematic structural diagram of an intermediate product obtained after performing the step 103 is as shown in FIG. 4.

Step 104, plating a metal conducting film on the electrode surface of the flip chip 1 and the surface of the encapsulation substrate, so as to be used as an electrode of electroforming process, wherein, the metal conducting film comprises a gold conducting layer 4 and a chromium conducting layer 5, and the chromium conducting layer 5 is located above the electrode surface of the flip chip 1 and the surface of the encapsulation substrate, and the gold conducting layer 4 is located above the chromium conducting layer 5, and preferably, the gold conducting layer has a thickness of 50 nm, and the chromium conducting layer has a thickness of 20 nm, and a schematic structural diagram of an intermediate product obtained after performing the step 104 is as shown in FIG. 5.

Step 105, coating photoresist 6 on a surface of the metal conducting film (specifically, the gold conducting layer 4), and in the embodiment, the photoresist is AZ4620 photoresist, and the AZ4620 photoresist is coated in a rotary method, and the rotational speed is 1000 revolutions per minute, and then the metal conducting film is dried in an oven at 90° C., and a schematic structural diagram of an intermediate product obtained after performing the step 105 is as shown in FIG. 6.

Step 106, aligning electrode structure on a photoetching plate with electrode structure of the flip chip 1 on a photoetching machine and performing photoetching, and obtaining a photoresist structural model in which the electrode surface of the flip chip 1 and the surface of the encapsulation substrate are in same region after exposure and development, and an insulating part between electrodes of the flip chip is covered with the photoresist 6, and a schematic structural diagram of an intermediate product obtained after performing the step 106 is as shown in FIG. 7.

Step 107, using the metal conducting film to perform electroforming growth of copper inside the photoresist structural model, and the specific operations are: the metal conducting film being used as an electrode, and electroforming the metal of copper 7 on the electrode surface of the flip chip 1 and the surface of the encapsulation substrate in the photoresist structural model simultaneously, and controlling time and growing speed to ensure that interior of the photoresist structural model in which the electrode surface of the flip chip and the surface of the encapsulation substrate are in same region is overgrown by the metal of copper 7, and to realize connection between the electrode of the flip chip 1 and the encapsulation substrate by means of the metal of copper 7, and a schematic structural diagram of an intermediate product obtained after performing the step 107 is as shown in FIG. 8.

Step 108, using a sol solution to dissolve an unexposed photoresist 6, and a schematic structural diagram of an intermediate product obtained after performing the step 108 is as shown in FIG. 9.

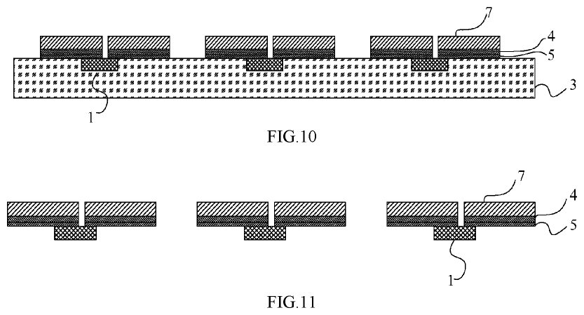

Step 109, using a gold corrosion solution to erode the gold conducting layer covered by the photoresist removed in the step 108, and using a chromium corrosion solution to erode the chromium conducting layer covered by the gold conducting layer, thus cutting off the electric connection between electrodes of the flip chip, and a schematic structural diagram of an intermediate product obtained after performing the step 109 is as shown in FIG. 10.

Step 110, using an organic glass solvent to dissolve the organic sheet (i.e. encapsulation substrate), so as to complete the encapsulation of the flip chip 2, and a schematic structural diagram of a product obtained after performing the step 110 is as shown in FIG. 11.

Wherein, in the embodiment, the flip chip may be specifically LED flip chip, and in specific implementation process, the electrode surface of the flip chip 1 itself is provided with or without a metal layer, and the surface of the encapsulation substrate itself is provided with or without a metal layer.

### Embodiment 2

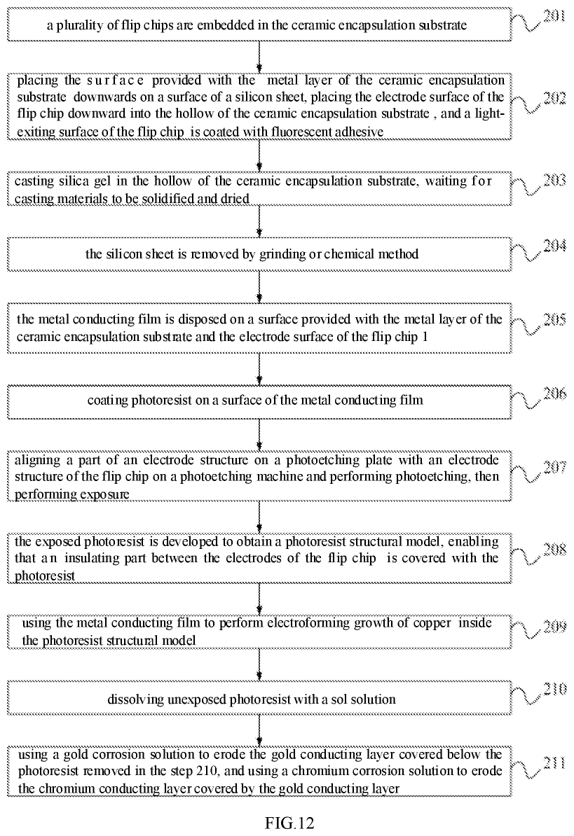

The main difference between this embodiment and the embodiment 1 lies in that: in this embodiment, the encapsulation substrate is a ceramic encapsulation substrate. As shown in FIG. 12, the encapsulation method for the flip chip in the embodiment comprises the following steps:

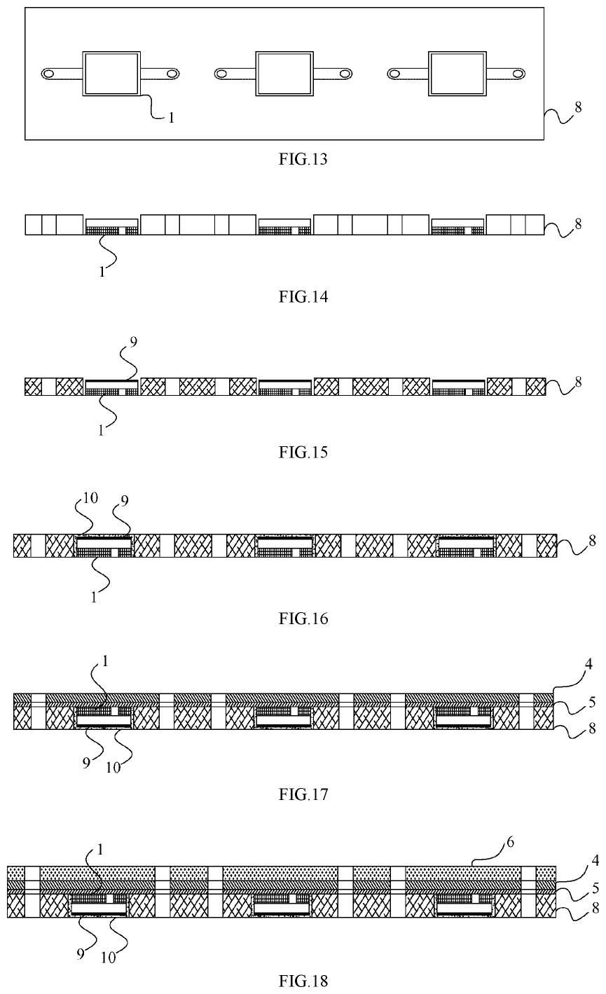

Step 201, a plurality of flip chips 1 are embedded in the ceramic encapsulation substrate 8, and in the embodiment, the flip chips are specifically LED flip chips of 1 mm in length, 1 mm in width and 0.35 mm in thickness, and the type is specifically CREEDA1000, and specific operations are as follows: providing a ceramic encapsulation substrate 8 having a thickness (about 0.6 mm) slightly larger than the thickness of the flip chip 1, and the unit center of each ceramic encapsulation substrate 8 is provided with a hollow notch which is consistent with the shape of the chip but slightly larger in size, and the substrate 8 having a side surface provided with a metal layer corresponding to and insulated from the two electrodes of the flip chip 1 and a through hole having a metal connection with the metal layer for the external heat sink, and a top view and a side view of an intermediate product obtained after performing the step 201 are as shown in FIG. 13 and FIG. 14, respectively.

Step 202, placing the surface provided with the metal layer of the ceramic encapsulation substrate 8 downwards on a surface of a silicon sheet, placing the electrode surface of the flip chip 1 downward into the hollow of the ceramic encapsulation substrate 8, and a light-exiting surface of the flip chip 1 is coated with fluorescent adhesive 9 and alternatively can be provided with a fluorescent film, and a schematic structural diagram of an intermediate product obtained after performing the step 202 is as shown in FIG. 15.

Step 203, casting silica gel 10 in the hollow of the ceramic encapsulation substrate 8, waiting for casting materials to be solidified and dried, so that the flip chip 1 and the ceramic encapsulation substrate 8 are fixed by the silica gel 10, and a schematic structural diagram of an intermediate product obtained after performing the step 203 is as shown in FIG. 16.

Step 204, the silicon sheet is removed by grinding or chemical method, so as to obtain an array having the flip chip 1 fixed with the ceramic encapsulation substrate 8 by the silica gel 10, and the electrode surface of the flip chip 1 and the surface of the ceramic encapsulation substrate 8 are well coincide.

Step 205, the metal conducting film is disposed on a surface provided with the metal layer of the ceramic encapsulation substrate 8 and the electrode surface of the flip chip 1, and the metal conducting film also comprises the gold conducting layer 4 and the chrome conducting layer 5, and specific arrangement is the same as that in the step 104 of embodiment 1, and a schematic structural diagram of an intermediate product obtained after performing the step 205 is as shown in FIG. 17.

Step 206, coating photoresist 6 on a surface of the metal conducting film (specifically, the gold conducting layer 4), and performing method is the same as that in the step 105 of embodiment 1, and a schematic structural diagram of an intermediate product obtained after performing the step 206 is as shown in FIG. 18.

Step 207, aligning a part of an electrode structure on a photoetching plate with an electrode structure of the flip chip 1 on a photoetching machine and performing photoetching, then performing exposure, so that one electrode N of the flip chip 1 and the corresponding surface metal of the ceramic encapsulation substrate 8 are in one region and the surface metal of the ceramic encapsulation substrate 8 corresponding to the other electrode P is in another region.

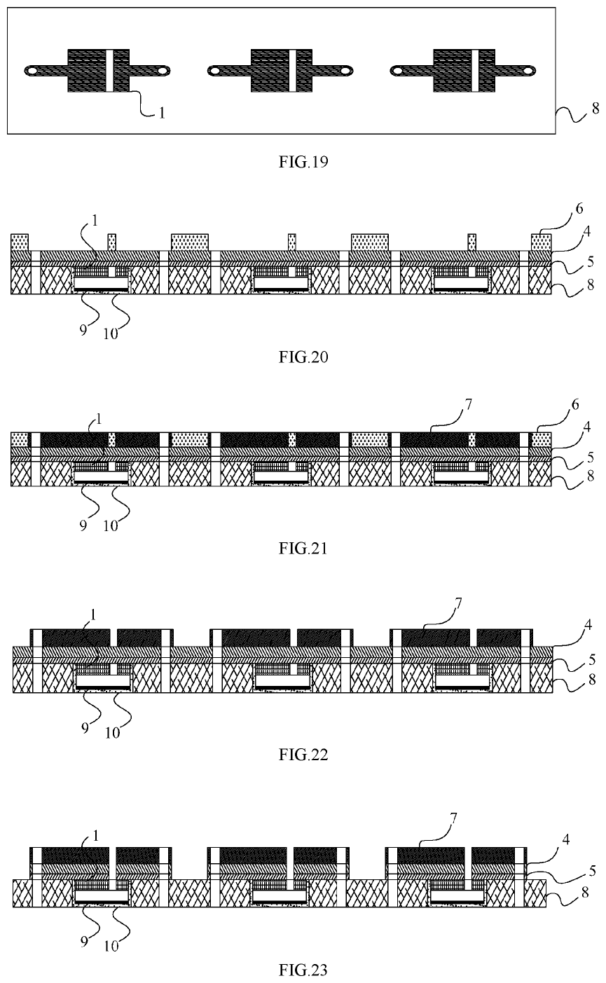

Step 208, the exposed photoresist is developed to obtain a photoresist structural model in which the electrode surface of single flip chip and the corresponding surface of the ceramic encapsulation substrate 8 are in the same region, enabling that an insulating part between the electrodes of the flip chip 1 is covered with the photoresist 6, and the top view and the side view of an intermediate product obtained after performing the step 208 are as shown in FIGS. 19 and 20, respectively.

Step 209, using the metal conducting film to perform electroforming growth of copper inside the photoresist structural model, and the specific operations are the same as that in the step 107 of embodiment 1, and a schematic structural diagram of an intermediate product obtained after performing the step 209 is as shown in FIG. 21.

Step 210, dissolving unexposed photoresist 6 with a sol solution, and a schematic structural diagram of an intermediate product obtained after performing the step 210 is as shown in FIG. 22.

Step 211, using a gold corrosion solution to erode the gold conducting layer covered below the photoresist removed in the step 210, and using a chromium corrosion solution to erode the chromium conducting layer covered by the gold conducting layer, thus cutting off the electric connection between electrodes of the flip chip, and a schematic structural diagram of a product obtained after performing the step 211 is as shown in FIG. 23.

### Embodiment 3

The present Embodiment provides a method for bonding electrodes of a flip-chip die to corresponding electrical contacts of an encapsulation substrate.

In particular, to make the description of the invention clear, the term “flip-chip die” here used means a functional semiconductor component before being bonded to and encapsulated by a substrate. The term “flip chip” here used means a finished semiconductor product after bonding and encapsulation and being cut into individual units that comprises one or more flip-chip dies and encapsulation substrate and has complete functionalities.

In the present Embodiment, the flip-chip die has an electrode surface with at least two electrodes and a base surface opposite the electrode surface.

The present Embodiment specifically uses an LED flip-chip die as the flip-chip die, and the type of the LED flip-chip die can be selected according to practical requirements, such as the LED flip-chip die for lights, the LED flip-chip die for screen display, the LED flip-chip die for ultraviolet radiation, etc. It should be understood that the LED flip-chip die here is only used as an example to illustrate the present Embodiment, and other types of flip-chip dies may also be used in other Embodiments.

The encapsulation substrate comprises a substrate body having a structured surface with at least two electrical contacts and a back surface opposite the structured surface, and the major material of the substrate body can be selected according to practical requirements, such as silicon, resin, ceramic, glass, etc.

In the present Embodiment, when the LED flip-chip die is used for lighting usage or screen display, the major material of the substrate body can be silicon or resin. When the LED flip-chip die is used for ultraviolet radiation, in order to avoid ultraviolet light from damaging the substrate body, the material of the substrate body is preferably a specific material that cannot be damaged by ultraviolet light, such as glass, metal, etc.

It should be understood that the structured surface here means a surface of the substrate body that can be provided with a circuit structure according to practical requirements. The circuit structure can be a conventional circuit such as a control circuit for controlling the functionality of the flip chip and/or an interface circuit for functionally connecting the electrical contacts of the encapsulation substrate to an external circuit. Electrical components included in the circuit structure and the connection relationship between the components can be conventional as known in the state of art.

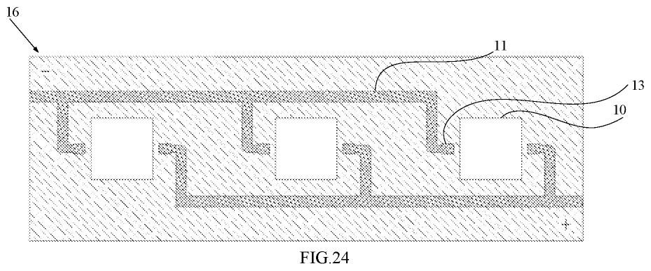

FIG. 24 shows a top view of part of the encapsulation substrate in the present Embodiment. The substrate body of the encapsulation substrate is provided with a number of hollow structures. Each of the hollow structures 10 passes through the substrate body to form a through hole with shape and size matching a flip-chip die, and the surface of the substrate body is pre-set with a circuit structure 11 connected to the electrical contacts 13 on the structural surface.

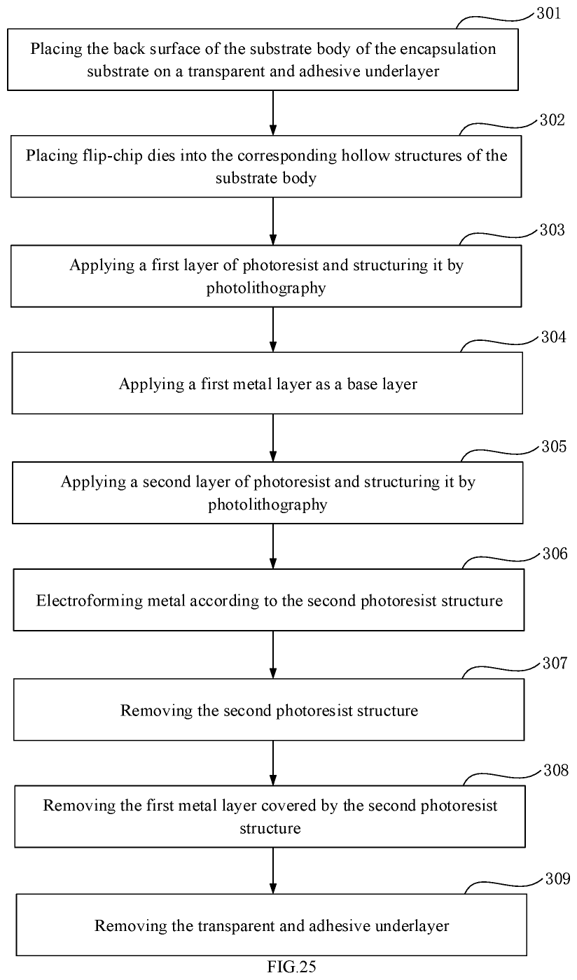

As shown in FIG. 25, the method includes the following steps:

S301. Placing the back surface of the substrate body of the encapsulation substrate on a transparent and adhesive underlayer.

By being attached to the transparent and adhesive underlayer, the encapsulation substrate can be mounted in a stable manner, so that the flip-chip die can be well fit in the following step, and light is permitted to transmit through this underlayer.

S302. Placing flip-chip dies into the corresponding hollow structures of the substrate body.

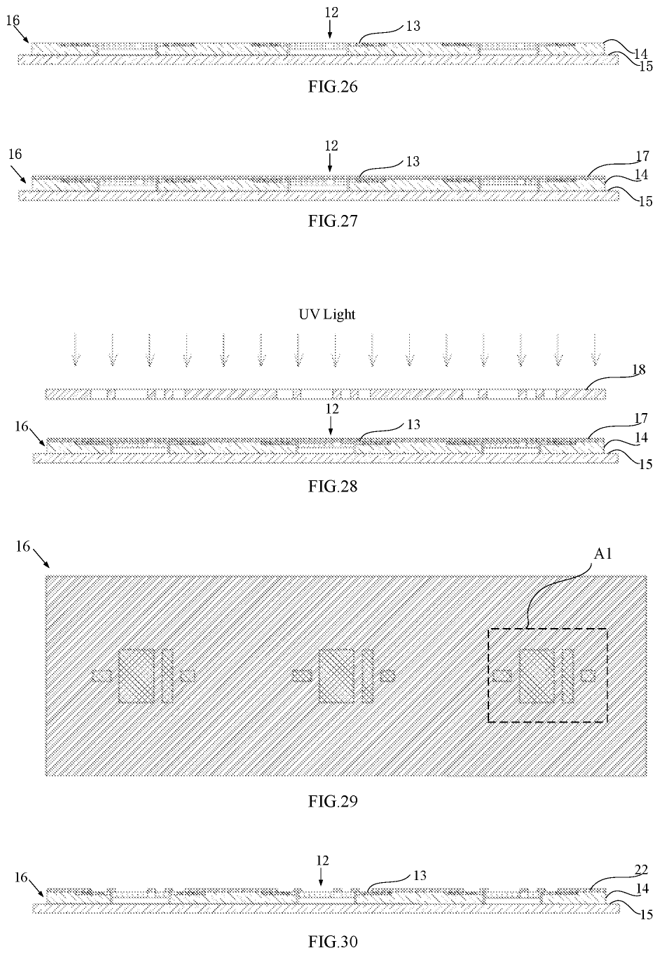

The intermediate product formed in S302 is shown in FIG. 26.

In this Embodiment, the electrode surface of the flip-chip die 12 is provided with at least two electrodes, and the structured surface of the substrate body 14 is provided with corresponding electrical contacts 13, wherein the structured surface of the substrate body 14 faces the same direction as the electrode surface of the flip-chip die 12. In a preferable arrangement, the substrate body 14 of the encapsulation substrate 16 and the flip-chip die 12 are of the same thickness, so that, when the flip-chip die 12 is placed into the corresponding hollow structure 10, the electrode surface of the flip-chip die 12 and the structured surface of the encapsulation substrate 16 are substantially on a same plane. With such an arrangement, it is easier to apply a layer of photoresist or a layer of metal on the electrode surface and the structured surface in the subsequent steps. For example, in a specific practical scenario, CREE DA1000 (trademark of Cree Inc.) LED chip is used as the flip-chip die 12, which has a length of 1 mm, a width of 5 mm and a thickness of 0.35 mm. Consequently, the thickness of the encapsulation substrate can be substantially 0.35 mm. “Substantially” here means a tolerance within tens of micrometers. In this example, the length of the hollow structure 10 can be 1 mm or a little larger, and the width of the hollow structure can be 5 mm or a little larger, so that a CTEE DA1000 LED chip can be well fit in the hollow structure.

In this step, when the flip-chip die 12 is embedded into the corresponding hollow structure 10, its back surface opposite the electrode surface can be attached to the transparent adhesive underlayer 15 too, since the flip-chip die 12 and the substrate body 14 (as well as the through-hole of the hollow structure 10) have the same thickness. In such a way, the flip-chip die 12 can well fit in the hollow structure 10 stably.

S303. Applying a layer of first photoresist and structuring it by photolithography.

In this step, a layer of first photoresist is applied on the common plane of the structured surface of the encapsulation substrate 16 and the electrode surface of the flip-chip die 12 for example by spin-coating.

Then structuring the layer of first photoresist by means of photolithography, so that the first photoresist in the areas on top of the electrodes of the flip-chip die and on top of the electrical contacts of encapsulation substrate is removed, while the first photoresist in other areas is remained, such as to form a first photoresist structure.

The type of the first photoresist used in Step S303 can be selected according to practical requirements, for example photosensitive polyimide (PSPI) photoresist widely used in the state of art.

As shown in FIG. 27, a layer of PSPI photoresist 17 is applied on the structured surface of the encapsulation substrate 16 and the electrode surface of the flip-chip die 12, and then the encapsulation substrate 16 with the embedded flip-chip die 12 is placed on a lithography machine.

As shown in FIG. 28, on the lithography machine, a mask 18 with a pre-set pattern is aligned with the structured surface of the encapsulation substrate and the electrode surface of the flip-chip die. Then the pattern on the mask 18 is transferred to the PSPI photoresist 17 through a process of exposure. In the process of exposure, the PSPI photoresist covering the electrodes of the flip-chip die 12 and the electrical contacts 13 of the encapsulation substrate 16 is exposed, while the PSPI photoresist covering other areas is not exposed.

After that, in a process of developing, the PSPI photoresist 17 in the exposed areas is dissolved by a developer, while the PSPI photoresist 18 in the unexposed areas is remained, such as to form a first photoresist structure 22. The exposed areas A1 in this step are shown in FIG. 29.

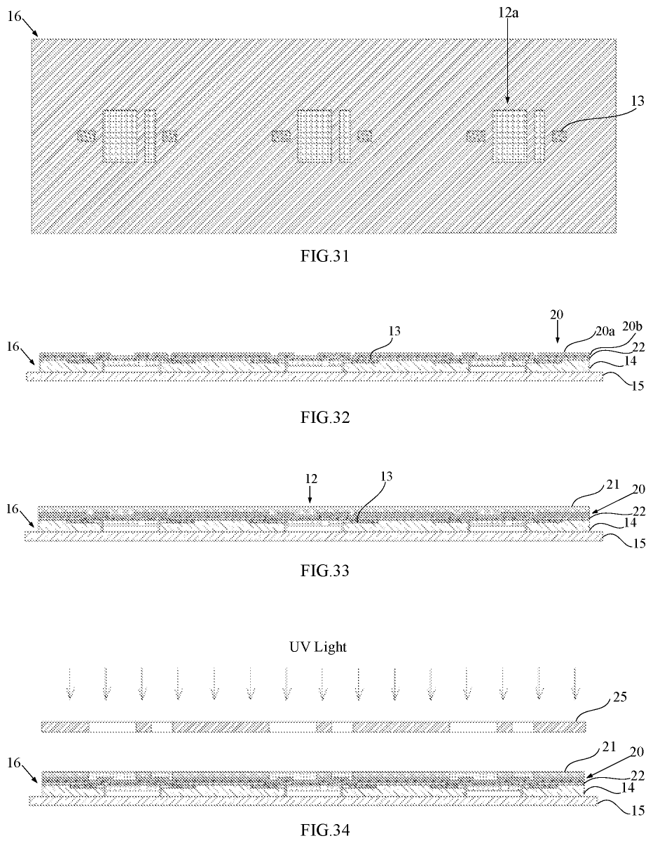

Through the above processes of exposure and developing, the pre-set pattern on the mask 18 is accurately copied to the layer of the PSPI photoresist 17, so that the electrodes of the flip-chip die and the corresponding electrical contacts of the encapsulation substrate 16 are not covered by the PSPI photoresist. As shown in FIG. 30, through step S303, the first photoresist structure 22 can be precisely formed on top of the non-electrode areas of the electrodes surface and the non-electric contacts areas of the structured surface. On the one hand, the first photoresist structure 22 can fill the gaps between the flip-chip die 12 and the encapsulation substrate 16, so that the flip-chip die 12 and the encapsulation substrate 16 can be stably connected. On the other hand, the first photoresist structure 22 can also serve as a buffer layer, which protects the surface structure of the flip-chip die 12 and the structural surface of the encapsulation substrate 16. FIG. 31 shows the top view of the immediate product, in which the exposed electrodes 12a of the flip-chip die 12 and the exposed electrical contacts 13 of the encapsulation substrate 16 as shown.

It should be understood that step S303 is an optional step for the present embodiment, and the present embodiment may not include the step S303, that is, step S304 can be performed immediately after step S302.

S304. Applying a first metal layer as a base layer.

As shown in FIG. 32, in the present embodiment, applying a first metal layer 20 on the electrodes, the electrical contacts 13 and the first photoresist structure 22 as a base layer.

However, in another embodiment, when there is no step S303, the first metal layer 20 can be directly applied on the electrode surface and the structured surface as the base layer.

The first metal layer 20 may include at least one layer of metal. In a preferred embodiment, the first metal layer includes a gold conductive layer 20a and a chromium conductive layer 20b, wherein the gold conductive layer 20a is applied on the chromium conductive layer 20b. In a specific scenario, the thickness of the gold conductive layer is 50 nm, and the thickness of the chromium conductive layer is 20 nm.

Thanks to good atomic binding force of chromium, the use of a chromium conductive layer can provide better binding strength between said first metal layer and the underlying surfaces. What's more, due to good conductivity and stability of gold, applying a gold conductive layer on the chromium conductive layer can facilitate the following electroforming process and achieve perfect bonding stability and conductivity of encapsulated chips.

It should be understood that applying the first layer metal 20 in step S304 can be done is various ways, such as electroplating, sputtering, etc., but is not limited to the example in this embodiment.

S305. Applying a layer of second photoresist and structuring it by photolithography.

In this step, a layer of second photoresist is applied on the first metal layer 20 for example by spin-coating.

Then structuring the layer of second photoresist by means of photolithography, so that the second photoresist, in the areas on top of the electrodes of the flip-chip die and on top of the electrical contacts 13 of the encapsulation substrate, as well as in the areas that are desired to form electrical connections between the electrodes and the corresponding electrical contacts 13, is removed to expose the underlying first metal layer, while the second photoresist in other areas is remained, such as to form a second photoresist structure.

The type of the second photoresist can be selected according to practical requirements. In the step of the present embodiment, AZ4620 photoresist (a general purpose i-line/h-line/g-line sensitive material) can be used as the layer of second photoresist. Specifically, AZ4620 photoresist can be applied on the base layer (specifically, the gold conductive layer) for example by spin-coating at a rotation speed of 1000 revolutions per minute, and then dried in an oven at 90° C.

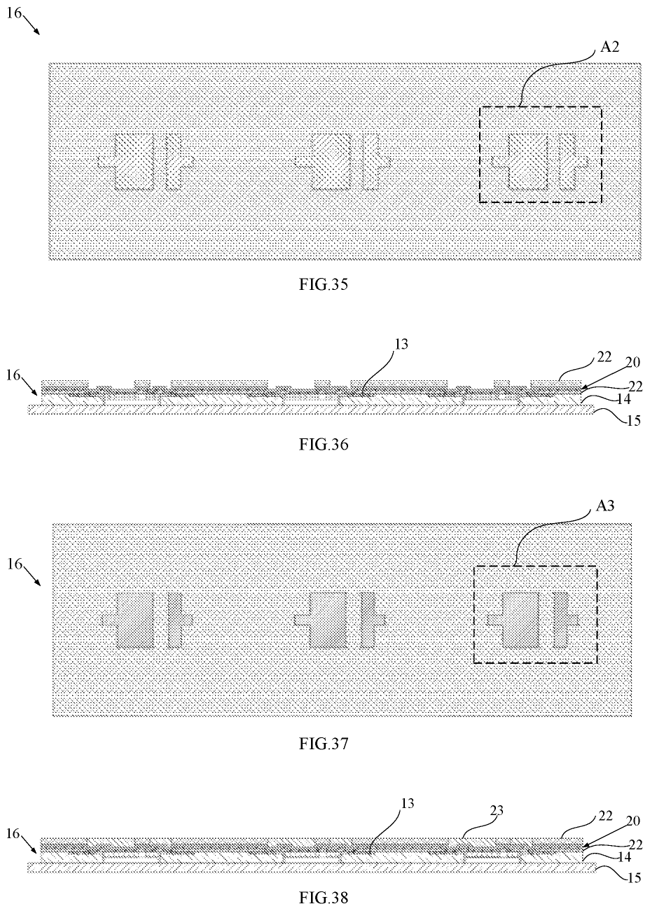

The process of photolithography can refer to the step S303. As shown in FIG. 33, coating a layer of AZ4620 photoresist 21 on the first metal layer 20, and, as shown in FIG. 34, aligning the pattern of a mask 25 with the base layer on the photoetching machine, and then, according to the pattern of the mask 25, exposing the layer of AZ4620 photoresist, so that the electrode N of the flip-chip die and the corresponding electrical contact of the encapsulation substrate 16 are located in a first area, and the electrode P of the flip-chip die and the corresponding electrical contact of the encapsulation substrate are located in a second area that is separate from the first area. The exposed areas A2 covered with the first metal layer 20 in this step are shown in FIG. 35. It should be understood that the first area and the second area are electrically isolated from each other, and then the layer of AZ4620 photoresist is developed so as to form the second photoresist structure 22 as shown in FIG. 36.

FIG. 37 shows the immediate product of the step S305, in which areas A3 represents the exposed electrodes of the flip-chip die 12, the exposed electrical contacts 13 of the encapsulation substrate 16 and the areas between the electrodes and corresponding electrical contact 13 where are desired to form electrical connections.

Through the step S305, the second photoresist structure 22 can be accurately formed in the non-electrodes areas, the non-electric contacts areas, and the areas in which no electrical connections are to be formed, so as to facilitate the subsequent step of electroforming metal according to the second photoresist structure 22.

S306. Electroforming metal according to the second photoresist structure.

In this step, according to the pattern of the second photoresist structure 22, electrical connections between electrodes of the flip-chip die 12 and the corresponding electrical contacts 13 of an encapsulation substrate 16 are formed by means of metal electroforming process.

As an exemplar embodiment, copper is used to perform the electroforming step. It should be understood that other metal may also be used to achieve electroforming in other embodiments.

As shown in FIG. 38, the first layer of metal 20 is used as a basic layer for electroforming growth of copper between the gaps in the second photoresist structure 22. Specifically, during the copper electroforming process, the first layer of metal 20 covering the electrodes of the flip-chip die 12 can be used as a first electrode and the first layer of metal 20 covering the corresponding electrical contacts 13 of the encapsulation substrate 16 can be used as a second electrode, and, by controlling the electroforming time and growth rate, copper 23 can grow between the first and second electrodes to fill the gaps according to the second photoresist structure 22. In such a way, electrical connections between the electrodes of the flip-chip die 12 and the corresponding electrical contacts 13 of the encapsulation substrate 16 are formed by means of the copper growth.

S307. Removing the second photoresist structure.

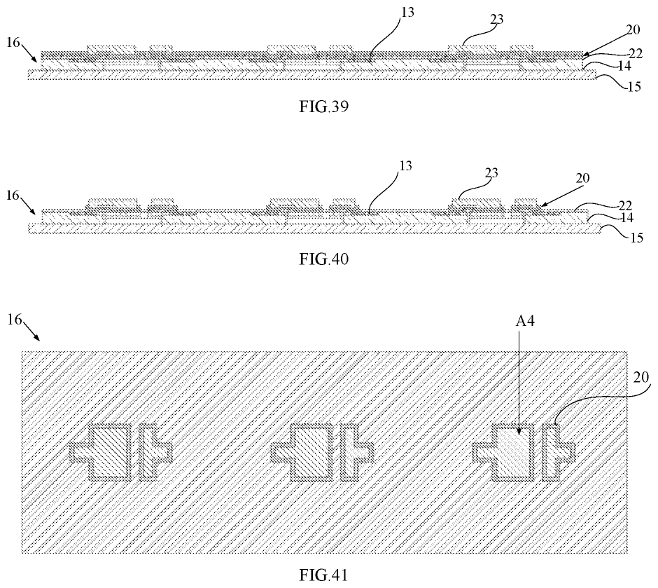

Specifically, using a sol solution to dissolve the second photoresist structure 22. The intermediate product formed in S307 is shown in the FIG. 39.

S308. Removing the first metal layer covered by the second photoresist structure.

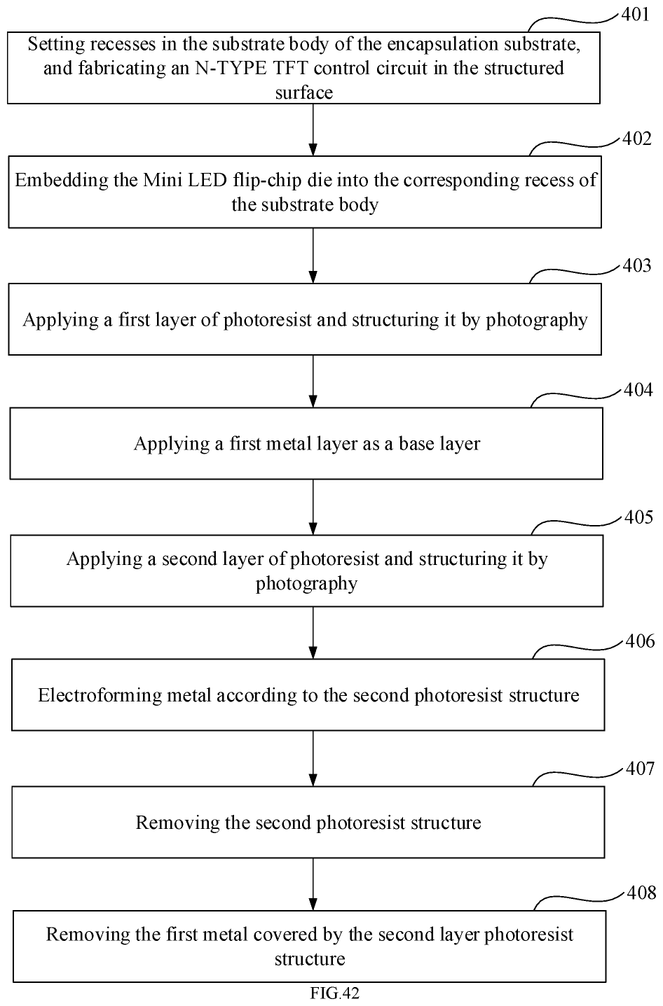

In this step, using a gold corrosion solution to erode the gold conductive layer 20 under the second photoresist structure 22 in the step S307, and then using a chromium corrosion solution to erode the chromium conducting layer 22 bunder the gold conductive layer, so as to cut off the electrical connections between different electrodes of the flip-chip die. The intermediate product formed in S308 is shown in FIG. 40.

S309. Removing the transparent and adhesive underlayer.

After S309, it may further include a step of cutting the encapsulated flip-chip dies into a plurality of chips. It should be understand the process of cutting can be performed according to practical requirements. For example, the cutting step can be either performed with respect to a single flip-chip die or in a group of flip-chip dies, such as a group of 2 or 3 flip-chip dies. As shown in FIG. 41, in the present embodiment, after cutting, a chip including three flip-chip dies that have been bonded to the encapsulation substrate are obtained as a finished product. In FIG. 41, area A4 represents the area that has been electrically connected between the electrodes of the flip-chip die and the corresponding electrical contacts of the encapsulation substrate. It should be understood that in this embodiment, in the top view 41, although a circle of the first metal layer 21 can still be seen around the periphery of area A4, however, in another embodiment, there may be no first metal layer 20 around the periphery of area A4, because when the first metal layer covered by the second photoresist structure is removed in step S308, the metal can be removed until the remained first metal layer completely coincides with the area A4.

In the present embodiment, the electrodes of the flip-chip die and the corresponding electrical contacts of the encapsulation substrate can be accurately bonded by metal electroforming. Since it has become a trend to make the LED flip-chip die smaller, it is difficult to achieve accurate electrical connections between the electrodes of the flip-chip die and the corresponding electrical contacts of the encapsulation substrate through traditional methods such as eutectic die bonding, solder paste die bonding, or silver glue die bonding. In the present embodiment, the electroforming bonding method overcomes the shortcomings of the traditional technology, and even for a very small LED flip-chip die, the subtle electrical connections between the electrodes of the flip-chip die and the corresponding electrical contacts of the encapsulation substrate can be formed with a high accuracy.

Furthermore, in the field of UVC, a large part of input power of a flip-chip die will be converted into heat energy. For example, a flip-chip die may require 100 mw of lighting energy and the efficiency for lighting is below 5%, in other words, the flip-chip die needs an input energy of 2000 mw, of which 100 mw are used for UVC and the other 1900 mw of energy are converted into heat energy which needs to be dissipated. Therefore, the bonding between the flip-chip die and the encapsulation substrate normally needs to dissipate the heat though the encapsulation substrate. In the present embodiment, the heat energy generated by the flip-chip die is dissipated outward through the encapsulation substrate as a heat conductor, compared with the traditional technologies, the electrode of the flip-chip die and the electrical contacts of the encapsulation substrate are connected by atomic-level metal binding without interference of flux (such as tin, silver glue), which greatly improves the heat dissipation of the flip-chip die.

### Embodiment 4

The present Embodiment provides a method for bonding electrodes of a flip-chip die to corresponding electrical contacts of an encapsulation substrate.

In the present embodiment, the basic structure of the flip-chip die and the encapsulation substrate is similar to Embodiment 3.

The difference between the present embodiment and Embodiment 3 is that the bonding method in Embodiment 4 uses even smaller flip-chip dies. In particular, the bonding method in the present Embodiment uses Mini LED flip-chip dies. For example, a Mini LED flip-chip die in Embodiment 4 has a length of 200 um, a width of 180 um and a thickness of 350 um. Since the size of an LED chip is far smaller relative to the size of the encapsulation substrate, in order to make it convenient to place the Mini LED flip-chip dies on the encapsulation substrate, in the present embodiment, the flip-chip dies are directly placed on the structural surface of the substrate body. In a preferred embodiment, in order to facilitate setting the position of the Mini LED flip-chip dies on the structured surface of the encapsulation substrate, a circuit structure can be used to embrace and define the position matching the size of the Mini LED flip-chip dies in the structured surface.

The substrate body of the encapsulation substrate may have recesses to make the top of the electrodes of the Mini LED flip-chip dies and the top of the electrical contacts substantially on the same plane, when the Mini LED flip-chip dies are embedded into the corresponding recesses. These recesses do not pass through the substrate body, and the shape, size and thickness of each of the recesses can match the corresponding Mini LED flip-chip die. It should be understood that, if technically permissible, in the present embodiment, the substrate body may also be provided with a hollow structure for placing the Mini LED flip-chip die.

Hereinafter, the present Embodiment will be described by taking the substrate body provided with a plurality of recesses as an example, and the structural surface of the substrate body is provided with a TFT control circuit for controlling the functionalities, such as emission colors, emission time, etc., of the Mini LED flip-chip dies. In the present embodiment, a common electrode and a source electrode of the TFT control circuit are used as the electrical contacts of the encapsulation substrate. As shown in FIG. 42, the method includes the following steps.

S401. Setting recesses in the substrate body of the encapsulation substrate, and fabricating an N-TYPE TFT control circuit in the structured surface.

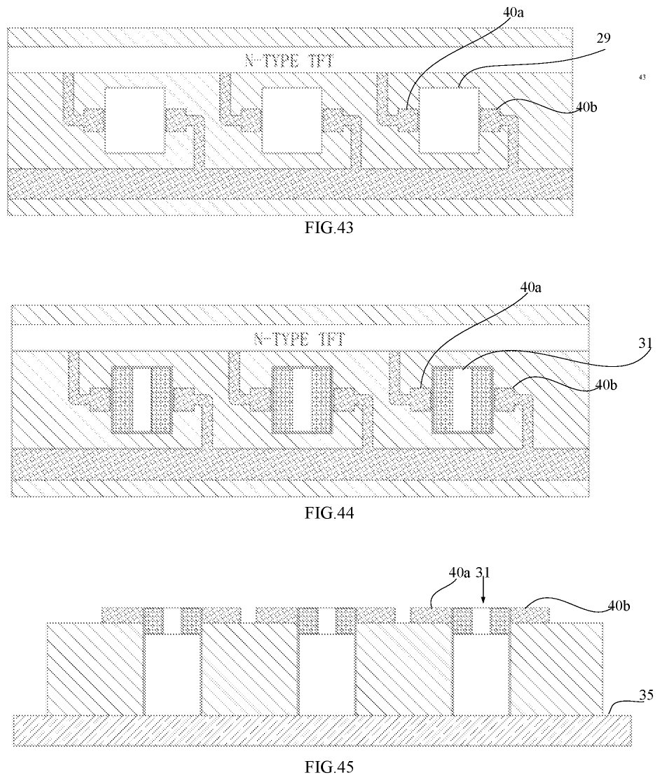

As shown in FIG. 43, in this step, for each recess 29, on the encapsulation substrate, the source electrode 40a of the N-TYPE TFT control circuit is arranged on one side, and the common electrode 40b of the N-TYPE TFT is arranged on the other side, and the source electrode 40a and the common electrode 40b are respectively used as different electrical contacts of the encapsulation substrate.

S402. Embedding the Mini LED flip-chip die into the corresponding recess of the substrate body.

As shown in FIG. 44 and FIG. 45, one electrode of the flip-chip die corresponds to the source electrode 40a of the N-TYPE TFT control circuit, and the other electrode of the flip-chip die corresponds to the common electrode 40b of the N-TYPE TFT control circuit.

It should be understood that, although there is an underlayer 35 shown in FIG. 42, in the present embodiment, the underlayer 35 is not necessary and can be omitted under certain circumstances.

S403. Applying a layer of first photoresist and structuring it by photography.

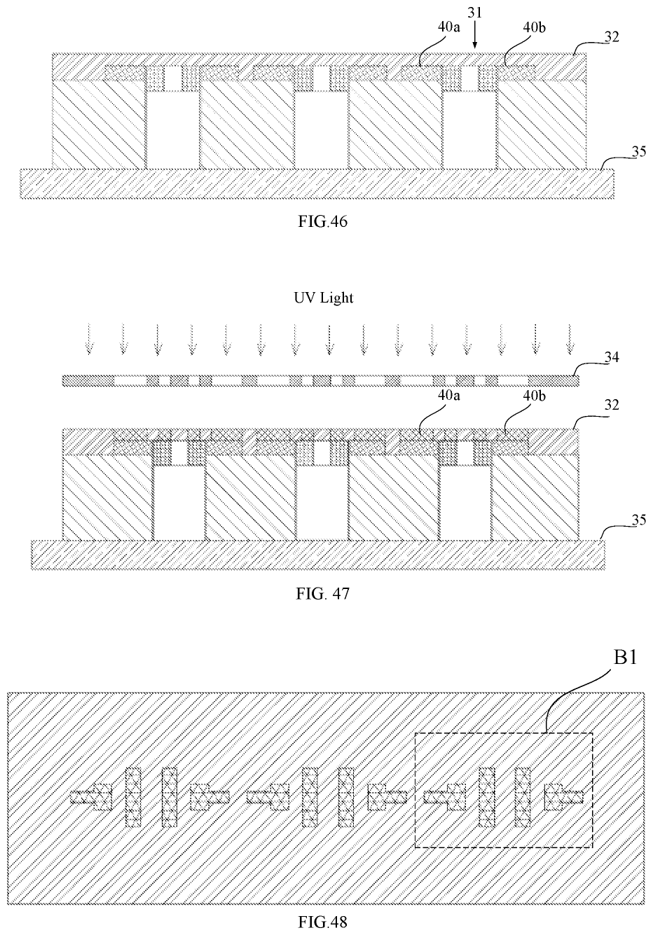

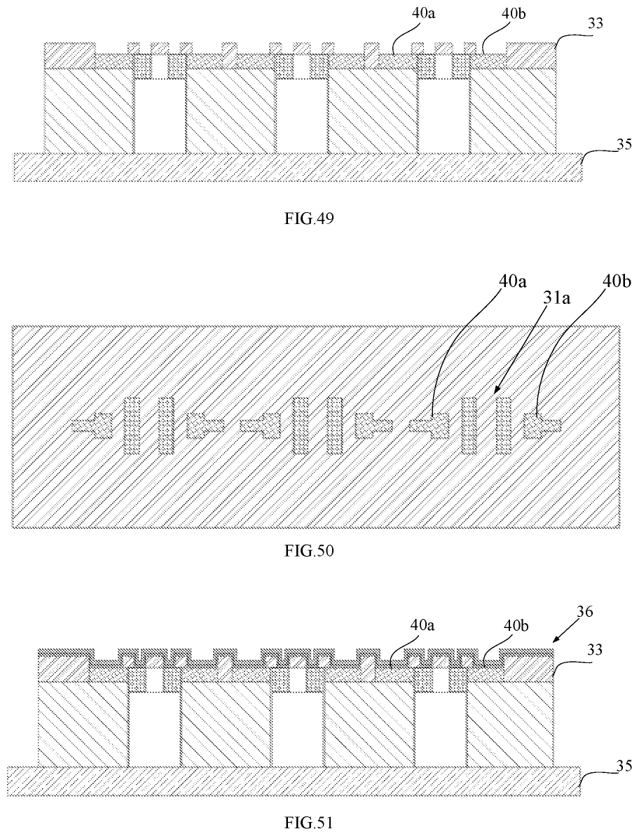

As show in FIGS. 46 and 47, in this step S403, coating a layer of first photoresist 32 on top of the encapsulation substrate and the Mini LED flip-chip dies 31 for example by spin-coating. Then performing the process of exposing and developing, using a mask 34. The first photoresist in the areas on top of electrodes of the Mini LED flip-chip dies 31, as well as on top of the source electrode and the common electrode of the N-TYPE TFT control circuit, is exposed and then dissolved, while the first photoresist in other unexposed areas is remained, such as to form a first photoresist structure 33. The exposed areas B1 in this step are shown in FIG. 48.

The intermediate product formed in step S403 is shown in FIGS. 49 and 50, FIG. 50 shows the top view of the immediate product, in which the exposed electrodes 31a of the flip-chip die 12 and the exposed source electrode 40a and the exposed common electrode 40b of the encapsulation substrate as shown, and the specific implementation process of this step can refer to the specific implementation process of step 303 in Embodiment 3.

S404. Applying a first metal layer as a base layer.

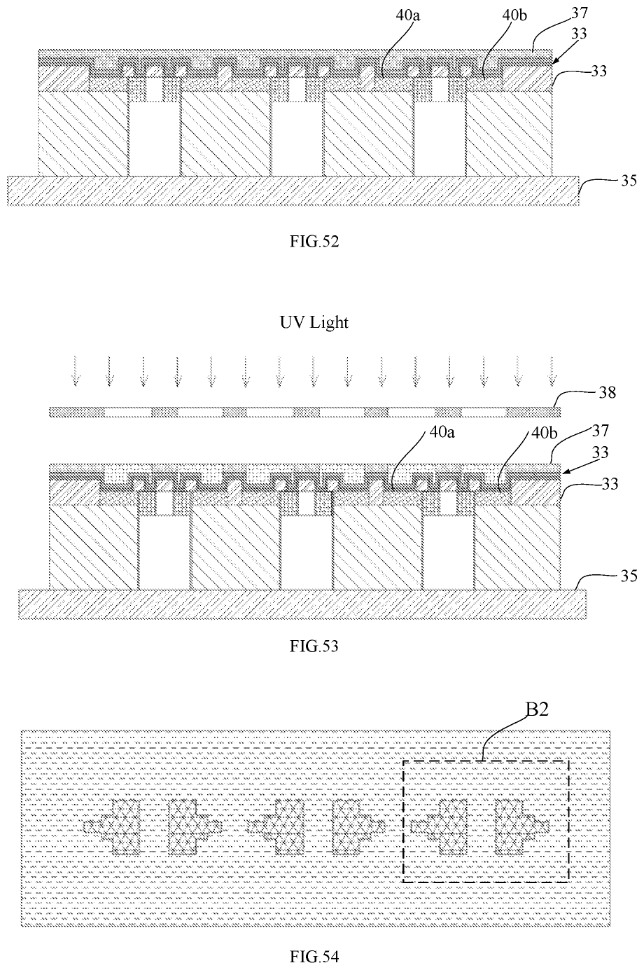

The intermediate product formed in the step S404 is shown in FIG. 51, wherein the first metal layer 36 has been formed, and the specific implementation process of this step can refer to the specific implementation process of step S304 in Embodiment 3.

S405. Applying a layer of second photoresist and structuring it by photography

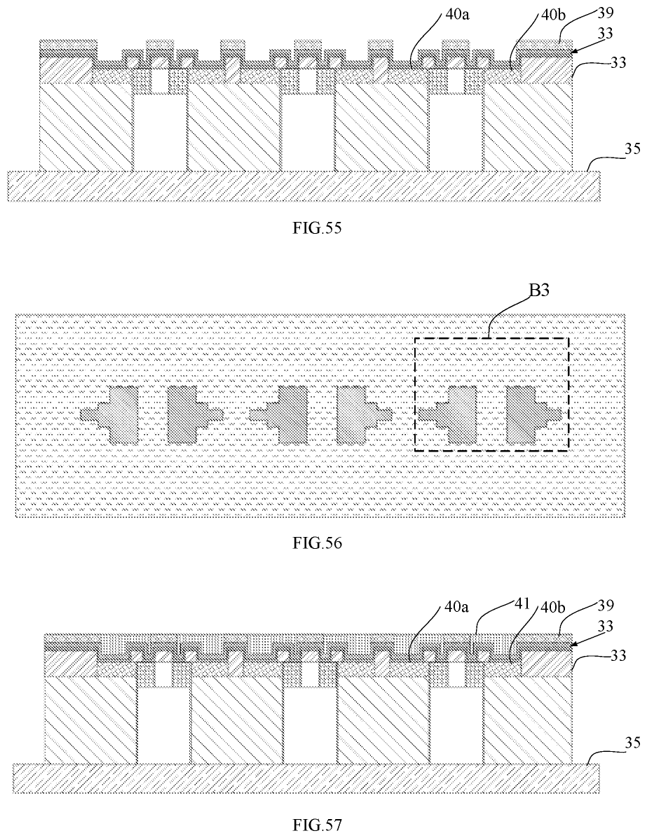

As shown in FIGS. 52 and 53, coating a layer of second photoresist 37 on the base layer. By means of the process of exposing and developing using a mask 38, one electrode of the Mini LED flip-chip die 31 and the corresponding source electrode 40a of the N-TYPE TFT control circuit of the encapsulation substrate are located in a first area, and the other electrode of the flip-chip die and the corresponding common electrode 40b of the N-TYPE TFT control circuit of the encapsulation substrate are located in a second area that is separate from the first area. The exposed areas B2 covered with the first metal layer 20 in this step are shown in FIG. 54.

The intermediate product formed in step S405 is shown in FIGS. 55 and 56. In FIG. 56, the areas B3 represents the exposed electrodes of the Mini LED flip-chip die 31, the exposed source electrode 40a and the common electrode 40b of the encapsulation substrate 30, as well as the areas between the electrodes and corresponding source electrodes or common electrodes where electrical connections are to be formed. In FIG. 55, numeral 39 represents the second photoresist structure. And the specific implementation process of this step can refer to the specific implementation process of step S305 in Embodiment 3.

S406. Electroforming metal according to the second photoresist structure.

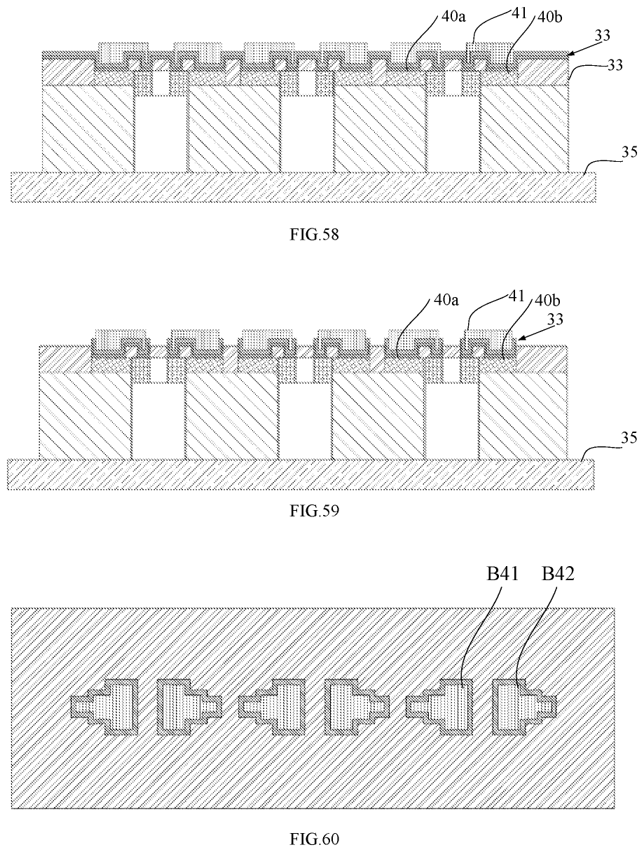

As shown in FIG. 57, in this step, by means of electroforming metal, for example copper 41, to fill the gaps in the second photoresist structure, one electrode of the Mini LED flip-chip die 31 is electrically connected to the corresponding source electrode 40a of the N-TYPE TFT control circuit of the encapsulation substrate 30, and the other electrode of the Mini LED flip-chip die 31 is electrically connected to the corresponding common electrode 40b of the N-TYPE TFT control circuit of the encapsulation substrate 30, and the specific implementation process of this step can refer to the specific implementation process of step S306 in Embodiment 3.

S407. Removing the second photoresist structure.

The intermediate product formed in step S407 is shown in FIG. 58, and the specific implementation process of this step can refer to the specific implementation process of step S407 in Embodiment 3.

S408. Removing the first metal covered by the second photoresist structure.

The intermediate product formed in the step 408 is shown in FIG. 59, and the specific implementation process of this step can refer to the specific implementation process of the step 408 in Embodiment 3.

After S309, it may further include a step of cutting the encapsulated flip-chip dies into a plurality of chips. The specific cutting step can refer to the specific implementation process of the cutting step in Embodiment 3. As shown in FIG. 60, in the present embodiment, after cutting, a chip including three flip-chip dies that have been bonded to the encapsulation substrate are obtained as a finished product. In FIG. 41, area B41 represents a area that has formed electrical connection between the source electrode 40a of the encapsulation substrate and the corresponding electrode of the flip-chip die, and area B42 represents a area that has formed electrical connection between the common electrode 40b of the encapsulation substrate and the corresponding electrode of the flip-chip die.

With the development of display technology in the field of LED display screen, an LED display screen may use tens of thousands or even millions of Mini LED flip-chip dies. On one hand, due to the small size of the flip-chip die, it is difficult to align the electrodes of the flip-chip die and the electrical contacts of the encapsulation substrate. On the other hand, in the state of art, it is necessary to use flux and preset proper pressure or temperature conditions to achieve bonding between the flip-chip die and the encapsulation, which significantly reduces the efficiency of mass production. In the present embodiment, through a series of steps such as metal-electroforming and photolithography, precise bonding between the flip-chip dies and the encapsulation substrate can be achieved, even if smaller Mini LED flip-chip dies are used, and the present embodiment does not need to use flux or set extra situations for bonding. The method in the present embodiment simplifies the bonding process, and greatly improves the efficiency for bonding the flip-chip die and the encapsulation substrate.

### Embodiment 5

The present Embodiment illustrates a flip chip manufactured by the aforementioned bonding method. As shown in FIG. 41, the flip chip is the final product formed through the steps in Embodiment 3.

The flip chip comprising a flip-chip die 12 and an encapsulation substrate 16 surrounding the flip-chip die 12, wherein the flip-chip die 12 has an electrode surface with at least two electrodes and a base surface opposite the electrode surface, and the encapsulation substrate comprises a substrate body 14 having a structured surface with at least two electrical contacts and a back surface opposite the structured surface. The base surface of the flip-chip die 12 is placed into a hollow structure of the substrate body 14, with the electrode surface of the flip-chip die 12 and the structured surface of the substrate body 14 facing the same direction. In an optional embodiment, the electrode surface of the flip-chip die 12 and the structured surface of the substrate body 14 are substantially on a common plane, but there can be a tolerance within tens of micrometers.

It should be understood that the structured surface means a surface of the substrate body 14 provided with a circuit structure according to practical requirements. The circuit structure can be a conventional circuit such as a control circuit for controlling the functionalities of the flip chip and/or an interface circuit for electrically connecting the electrical contacts of the encapsulation substrate to an external circuit.

In the present embodiment, the flip chip comprises a layer of first photoresist 22 in non-electrodes areas of the electrode surface and non-electrical contacts areas of the structural surface, and the top of the electrodes of the flip-chip die and the top of the electrical contacts of the encapsulation substrate are covered with a first metal layer. However, it should be understood that, in other embodiments, said flip chip may not comprises the layer of first photoresist 22.

In a preferred embodiment, the first metal layer includes a gold conductive layer and a chromium conductive layer.

In the present Embodiment, the flip chip also comprises metal 20 in gaps between the electrodes of the flip-chip die 12 and the corresponding electrical contacts of the encapsulation substrate, such as to form electrical bonding between the electrodes of the flip-chip die 12 and corresponding electrical contacts of the encapsulation substrate, while there is no metal in isolation areas between different electrodes of the flip-chip die 12 and in isolation areas between different electrical contacts of the encapsulation substrate.

In the embodiment, the flip-chip dies can be LED flip-chip dies. The type of the LED flip-chip dies can be selected according to practical requirements, such as LED flip-chip dies for lighting applications, LED flip-chip dies for screen displays, LED flip-chip dies for ultraviolet radiation, etc. And the major material of the substrate body can be selected according to practical requirements, such as silicon, resin, ceramic, glass, etc. When the LED flip-chip die is used for lighting or screen displays, the major material of the substrate body can be silicon or resin. When the LED flip-chip die is used for ultraviolet radiation, the major material of the substrate body can be glass or metal. To achieve better luminous effect, the material of the substrate body can further include luminescent materials.

In the present embodiment, the electrical contacts of the encapsulation and the electrodes of the flip-chip die face the same direction and are substantially located on the same plane. In such a way the thickness of the finished flip chip can be made very small.

In the present embodiment, by setting the layer of first photoresist, the binding force between the various components in the flip chip can be enhanced, and, at the same time, the electrode surface of the flip-chip die and the structural surface of the encapsulation substrate can be protected by the first photoresist.

In the present embodiment, there is no additional soldering material used for bonding the flip-chip die to the encapsulation substrate. This is more cost effective and can further promote heat dissipation of the flip chip.

### Embodiment 6

The present Embodiment provides a flip chip. As shown in FIG. 60, the flip chip is the final product formed through the steps in Embodiment 4. The structure of the flip chip in this Embodiment is similar to the structure of the flip chip in Embodiment 5.

The difference is that in the present embodiment the flip-chip die is a Mini LED flip-chip die, which is much smaller than the flip-chip die in Embodiment 5, and the substrate body may not comprise hollow structures, as the flip-chip dies can be directly placed on the structural surface of the substrate. The structural surface can further comprises a circuit structure embracing the flip-chip dies to define the position of the flip-chip dies.

The substrate body of the encapsulation substrate in this embodiment may be provided with recesses, which do not pass through the substrate body. The shape, size and thickness of each of the recesses can match the flip-chip die. It should be understood that, if technically permissible, the substrate body may also have a hollow structure for placing the flip-chip dies. The structural surface of the substrate body can be also provided with a TFT control circuit for controlling functionalities, such as emission colors, emission time, etc., of the flip-chip dies, and the source electrode and the common electrode of the TFT control circuit can be used as the electrical contacts of the encapsulation substrate.

While illustrative embodiments of the invention have been illustrated and described, it will be appreciated that various changes can be made therein without departing from the spirit and scope of the invention.

We claim:

1. A method for bonding electrodes of a flip-chip die to corresponding electrical contacts of an encapsulation substrate,
wherein the flip-chip die has an electrode surface with at least two electrodes and a base surface opposite the electrode surface, and the encapsulation substrate comprises a substrate body having a structured surface with at least two electrical contacts and a back surface opposite the structured surface, and
wherein the base surface of the flip-chip die is placed in the substrate body or on the structured surface of the substrate body, so that the electrode surface of the flip-chip die and the structured surface of the substrate body face the same direction,
comprising steps of:
S11: applying a first metal layer on the electrode surface of the flip-chip die and the structured surface of the encapsulation substrate as a base layer;
S12: transferring, by means of photolithography, a structural pattern of a mask onto the base layer;
S13: electroforming metal, according to the transferred structural pattern, to form electrical connections between electrodes of the flip-chip die and the corresponding electrical contacts of an encapsulation substrate; and
S14: cutting off undesired electrical connections between different electrodes and between different electrical contacts by removing unnecessary metal areas.

2. The method according to claim 1, wherein step S12 comprising:
S121: applying a layer of a first photoresist on the first metal layer; and
S122: structuring the layer of the first photoresist by means of photolithography according to the structural pattern of the mask, so that in the areas on top of the electrodes of the flip-chip die and on top of the electrical contacts of the encapsulation substrate, as well as in the areas that are desired to form electrical connections between the electrodes and the corresponding electrical contacts, the first photoresist is removed to expose the underlying first metal layer, while in other areas the first photoresist is remained.

3. The method according to claim 2, wherein step S13 comprising:
S131: electroforming metal on the exposed portions of the first metal layer to fill the gaps between the remained first photoresist; and
S132: removing the remaining first photoresist to expose the underlying first metal layer.

4. The method according to claim 3, wherein step S13 comprising: removing the still exposed portions of the first metal layer.

5. The method according to claim 4, wherein step S11 comprising:
S111: applying a layer of a second photoresist on the electrode surface of the flip-chip die and the structured surface of the encapsulation substrate;
S112. structuring the layer of the second photoresist by means of photolithography, so that in the areas on top of the electrodes of the flip-chip die and on top of the electrical contacts of encapsulation substrate the second photoresist is removed, while in other areas the second photoresist are remained; and
S113: coating metal on the structured layer of the second photoresist, as well as on top of the exposed areas of the electrodes of the flip-chip die and the electrical contacts of encapsulation substrate, such as to form said first metal layer.

6. The method according to claim 5, wherein step S113 comprising: first coating a chromium layer and then coating a gold layer on top of the chromium layer.

7. The method according to claim 1, wherein the flip-chip die is placed in a recess or a hollow structure of the substrate body of the encapsulation substrate.

8. The method according to claim 7, wherein, the electrode surface of the flip-chip die and the structured surface of the substrate body are substantially on a common plane.

9. The method according to claim 7, wherein the flip-chip die is placed in a hollow structure of the substrate body of the encapsulation substrate, and said method further comprising S10 before step S11, placing the back surface of the substrate body of the encapsulation substrate on a transparent and adhesive underlayer, and, after S14, removing said transparent and adhesive underlayer.

10. The method according to claim 1, wherein a plurality of flip-chip dies are bonded to the same encapsulation substrate according to steps S11-S14 and then cut into a plurality of chips.

11. The method according to claim 1, wherein the flip-chip die is for an LED chip.

12. The method according to claim 1, wherein the substrate body is made of silicon, resin, glass or ceramic.

13. A flip chip comprising a flip-chip die and an encapsulation substrate, wherein the flip-chip die has an electrode surface with at least two electrodes and a base surface opposite the electrode surface, and the encapsulation substrate comprises a substrate body having a structured surface with at least two first electrical contacts and a back surface opposite the structured surface, and wherein the base surface of the flip-chip die is placed in the substrate body or on the structured surface of the substrate body, with the electrode surface of the flip-chip die and the structured surface of the substrate body facing the same direction, wherein
said flip chip further comprising a structured metal layer formed by metal-electroforming on top of the electrodes of the flip-chip die and on top of the electrical contacts of the encapsulation substrate, as well as in gaps between the electrodes of the flip-chip die and the corresponding electrical contacts of the encapsulation substrate, such as to form electrical bonding between the electrodes of the flip-chip die and corresponding electrical contacts of the encapsulation substrate, while there is no metal electroformed in isolation areas between different electrodes of the flip-chip die and in isolation areas between different electrical contacts of the encapsulation substrate.

14. The flip chip according to claim 13, wherein the encapsulation substrate further comprises a control circuit provided on the structured surface to control the functionality of the flip chip, wherein the control circuit is electrically connected to corresponding electrical contacts of the encapsulation substrate.

15. The flip chip according to claim 14, wherein, the encapsulation substrate further comprises an interface circuit on the structured surface for electrically connecting the flip chip to an external device, wherein the interface circuit is electrically connected to the control circuit.

16. The flip chip according to claim 13, wherein said flip chip is an LED chip.

17. The flip chip according to claim 13, wherein the substrate body of the encapsulation substrate is made of silicon, resin, glass or ceramic.

18. The flip chip according to claim 13, wherein the flip-chip die is placed in a recess or hollow structure of the substrate body of the encapsulation substrate.

19. The flip chip according to claim 18, wherein the electrode surface of the flip-chip die and the structured surface of the substrate body are substantially on a common plane.
